(19) United States
(12) Patent Application Publication
(10) Pub. No.: US 2019/0197936 A1
(43) Pub. Date: Jun. 27, 2019

(54) DISPLAY PANEL

(71) Applicant: Novatek Microelectronics Corp., Hsinchu (TW)

(72) Inventors: I-Chun Kuo, Hsinchu City (TW); Syang-Yun Tzeng, Taoyuan City (TW)

(73) Assignee: Novatek Microelectronics Corp., Hsinchu (TW)

(21) Appl. No.: 16/215,588

(22) Filed: Dec. 10, 2018

Related U.S. Application Data
(60) Provisional application No. 62/610,292, filed on Dec. 26, 2017.

(51) Int. Cl. G09G 3/20; H05K 1/18

(52) U.S. Cl. CPC G09G 3/20; H05K 1/189; G09G 2300/0408; G09G 2300/0426; H05K 2201/10128

(57) ABSTRACT

A display panel includes a substrate, a chip, a connecting portion, and a plurality of connecting lines. The substrate includes an active area where a pixel array is located and a peripheral area at a side of the active area. The peripheral area includes a chip region and a connecting region. The chip is mounted on the chip region of the peripheral area and electrically connected to the pixel array. The connecting portion is disposed on the connecting region of the peripheral area and configured to electrically connect a flexible printed circuit (FPC) board. The connecting region is overlapped with an extensional region extended from the chip region along a longitudinal axis of the chip. The connecting lines are electrically connecting the chip and the connecting portion.

### CROSS-REFERENCE TO RELATED APPLICATION

This application claims the priority benefit of U.S. provisional application Ser. No. 62/610,292, filed on Dec. 26, 2017. The entirety of the above-mentioned patent application is hereby incorporated by reference herein and made a part of this specification.

### BACKGROUND

### Technical Field

The present disclosure generally relates to a display panel. More particularly, the present disclosure relates to a display panel with narrow bezel.

### Description of Related Art

A display typically includes of an array (or matrix) of picture elements (“pixels”). Thousands or millions of these pixels together create an image on the display. The light modulators of the pixels are electronically driven by drive components, e.g., driver IC chips, which are located on the periphery of a display panel. A drive IC chip uses contact pads to connect with routing lines that conduct electrical signals to drive each row and column of the array of picture elements.

However, one problem is that a substrate of a conventional display panel usually requires relatively wide conductive routing lines or paths (e.g., 3-5 microns wide). Because a display can have many rows of pixels that require many routing lines to drive the many rows, the bezel width of the display must be wide enough to accommodate the many rows of routing lines and driver IC. With a design rule for the driver IC and routing paths of the routing lines, the bezel size can be undesirably large, resulting in less room for the display area for a particular size of display backplane. It would be beneficial to have a display with a relatively narrow bezel which, in turn, enables a larger viewable display area for the same display substrate area.

### SUMMARY

Accordingly, the present disclosure is directed to a display panel with narrower bezel enabling a larger viewable display area.

According to an embodiment of the present disclosure, a display panel includes a substrate, a chip, a connecting portion, and a plurality of connecting lines. The substrate includes an active area where a pixel array is located and a peripheral area at a side of the active area. The peripheral area includes a chip region and a connecting region. The chip is mounted on the chip region of the peripheral area and electrically connected to the pixel array. The connecting portion is disposed on the connecting region of the peripheral area and configured to electrically connect a flexible printed circuit (FPC) board. The connecting region is overlapped with an extensional region extended from the chip region along a longitudinal axis of the chip. The connecting lines are electrically connecting the chip and the connecting portion.

According to an embodiment of the present disclosure, the substrate further includes a plurality of fan-out lines connected between the pixel array and the chip.

According to an embodiment of the present disclosure, the chip is a display driver integrated circuit.

According to an embodiment of the present disclosure, a width of the connecting region is substantially equal to or smaller than a width of the chip region.

According to an embodiment of the present disclosure, the connecting portion is completely located within the extensional region.

According to an embodiment of the present disclosure, a display panel includes a substrate, a first chip, a second chip, a connecting portion, and a plurality of connecting lines. The substrate includes an active area where a pixel array is located and a peripheral area at a side of the active area. The peripheral area includes a first chip region, a second chip region and a connecting region, wherein the first chip region and the second chip region are arranged in a side by side manner. The first chip and the second chip are mounted on the first chip region and the second chip region respectively in the side by side manner, wherein the first chip and the second chip are electrically connected to the pixel array. The connecting portion is disposed on the connecting region of the peripheral area and configured to electrically connect a flexible printed circuit (FPC) board. The connecting region is overlapped with an extensional region extended from the first chip region to the second chip region. The connecting lines are electrically connecting the chips and the connecting portion.

According to an embodiment of the present disclosure, an electronic device, comprising: a substrate, comprising a connecting portion; at least one chip each mounted on the substrate; and a plurality of connecting lines electrically connecting the chip and the connecting portion, wherein the connecting portion is configured to be electrically connected between a circuit board and the at least one chip, and the connecting region is at least partially overlapped with an extensional region extended from the chip region along a longitudinal axis of the chip.

According to an embodiment of the present disclosure, the substrate further includes a plurality of fan-out lines connected between the pixel array and the first chip and the second chip.

According to an embodiment of the present disclosure, the first chip and the second chip are display driver integrated circuit.

According to an embodiment of the present disclosure, a width of the connecting region is substantially equal to or smaller than a width of each of the chip regions.

According to an embodiment of the present disclosure, the connecting portion is completely located within the extensional region.

According to an embodiment of the present disclosure, the connecting portion is partially located within the extensional region and partially located outside the extensional region.

In light of the foregoing, a peripheral area of a substrate includes a chip region where a chip is disposed, a connecting region for bonding a FPC board and an extensional region connecting region extended from the chip region along a longitudinal axis of the chip. The connecting region is overlapped with the extensional region. With such configuration, the required space for the peripheral area can be further reduced. Thereby, a narrower bezel (e.g. the peripheral area) of the display panel can be achieved. Thereby, the display panel of the disclosure is capable of providing a larger viewable display area.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates a schematic view of a display panel according to an embodiment of the disclosure.

FIG. 2 illustrates a partial enlarged of a display panel according to an embodiment of the disclosure.

FIG. 3 illustrates a partial enlarged of a display panel according to an embodiment of the disclosure.

FIG. 4 illustrates a schematic view of a display panel according to an embodiment of the disclosure.

FIG. 5 illustrates a partial enlarged of a display panel according to an embodiment of the disclosure.

FIG. 6 illustrates a partial enlarged of a display panel according to an embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts. The terms used herein such as “on”, “above”, “below”, “front”, “back”, “left” and “right” are for the purpose of describing directions in the figures only and are not intended to be limiting of the disclosure.

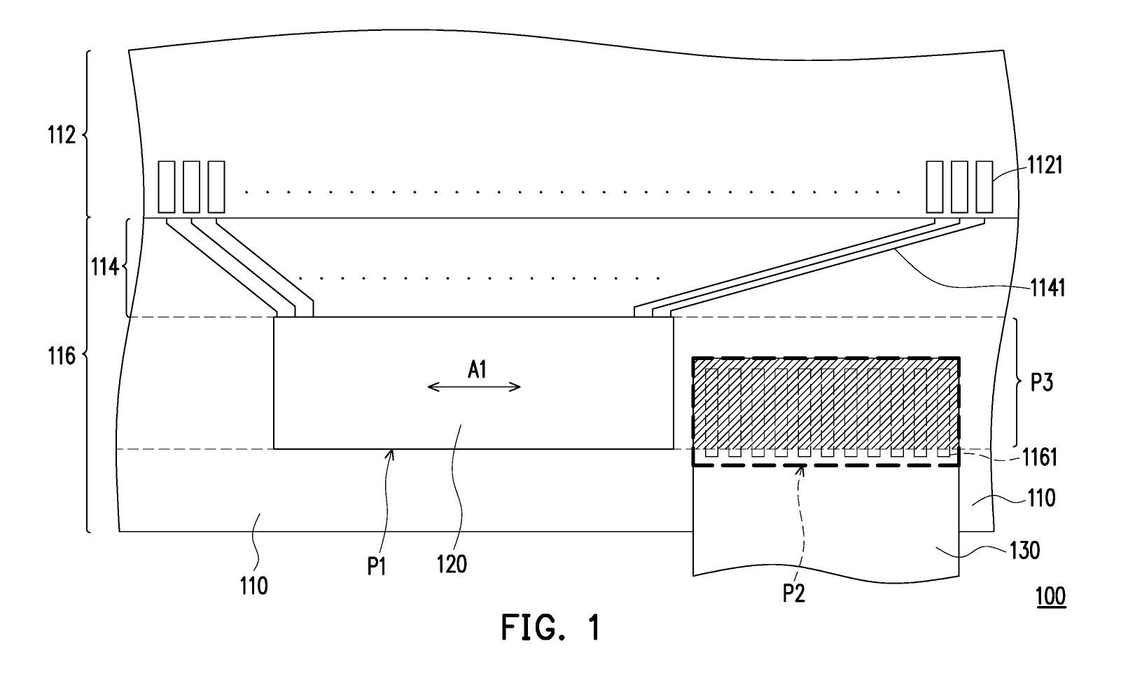

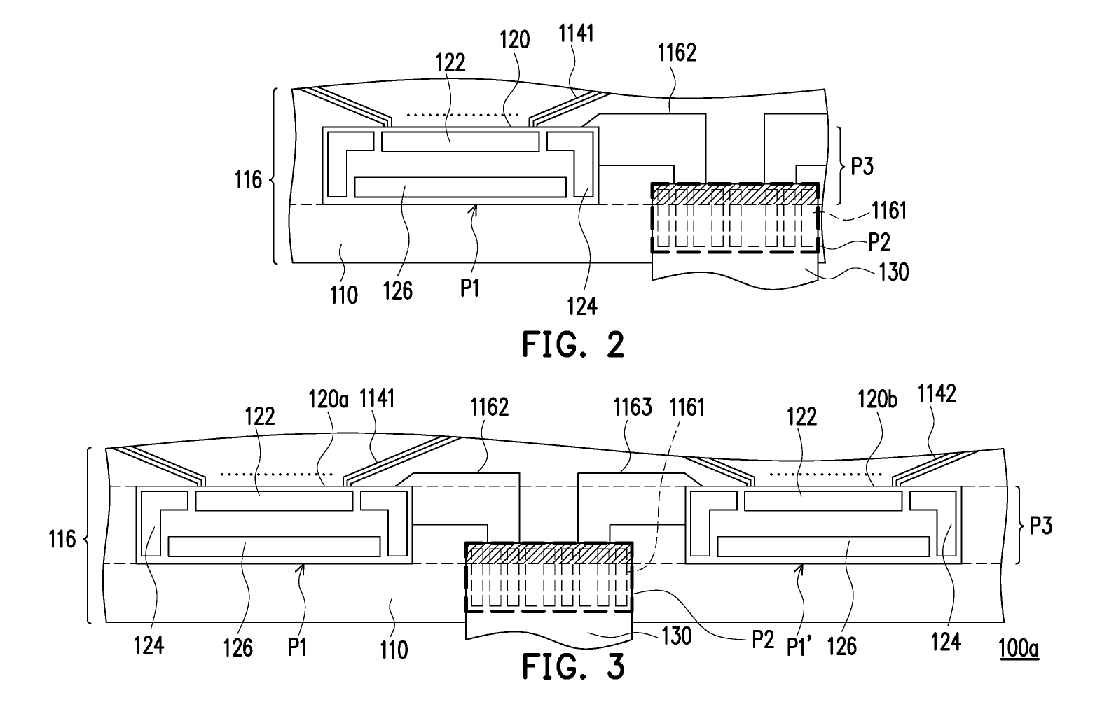

FIG. 1 illustrates a schematic view of a display panel according to an embodiment of the disclosure. FIG. 2 illustrates a partial enlarged of a display panel according to an embodiment of the disclosure. Referring to FIG. 1 and FIG. 2, in the present embodiments, the display panel 100 may be a liquid crystal display (LCD) panel, an organic light emitting diode (OLED) display panel, or any other display panels applicable. The display panel 100 includes a substrate 110, at least one chip 120, a connecting portion 1161 and a plurality of connecting lines 1162 (and connecting lines 1163 in the embodiment of FIG. 3). In some embodiments, the chip 120 is a display driver integrated circuit (IC) for driving the display panel 100.

In some embodiments, the substrate 110 includes an active area 112 and a peripheral area 116 adjacent to a side of the active area 112. In the present embodiment, a pixel array comprising a plurality of sub-pixels 1121 can be disposed on the active area 112. In addition, the peripheral area 116 further comprise a fan-out area 114, and a plurality of fan-out lines 1141 can be disposed on the fan-out area 114 of the substrate 110. The pixel array 1121 is formed by a plurality of pixel electrodes arranged in an array on the active area 112.

In some embodiments, the peripheral area 116 may be located adjacent to a side of the active area 112, and the fan-out lines 1141 are disposed on the peripheral area 116 for being connected between the sub-pixels 1121 of the pixel array and the chip 120 as shown in FIG. 1. In some embodiments, the peripheral area 116 may include at least one chip region (exemplarily shown as one chip region P1) and at least one connecting region (exemplarily shown as one connection region P2). The chip 120 is mounted on the chip region P1 of the peripheral area 116 and electrically connected to the pixel array. The connecting portion 1161 is disposed on the connecting region P2 of the peripheral area 116 and is configured to be electrically connected to a circuit board such as a flexible printed circuit (FPC) board 130. In other words, the FPC board 130 is bonded to the connecting region P2 of the peripheral area 116 through the connecting portion 1161. In some embodiments, the FPC board 130 is configured to electrically connect the display panel 100 to a main board (not shown). In some embodiments, the connecting portion 1161 may include a plurality of bonding pads as shown in FIG. 1.

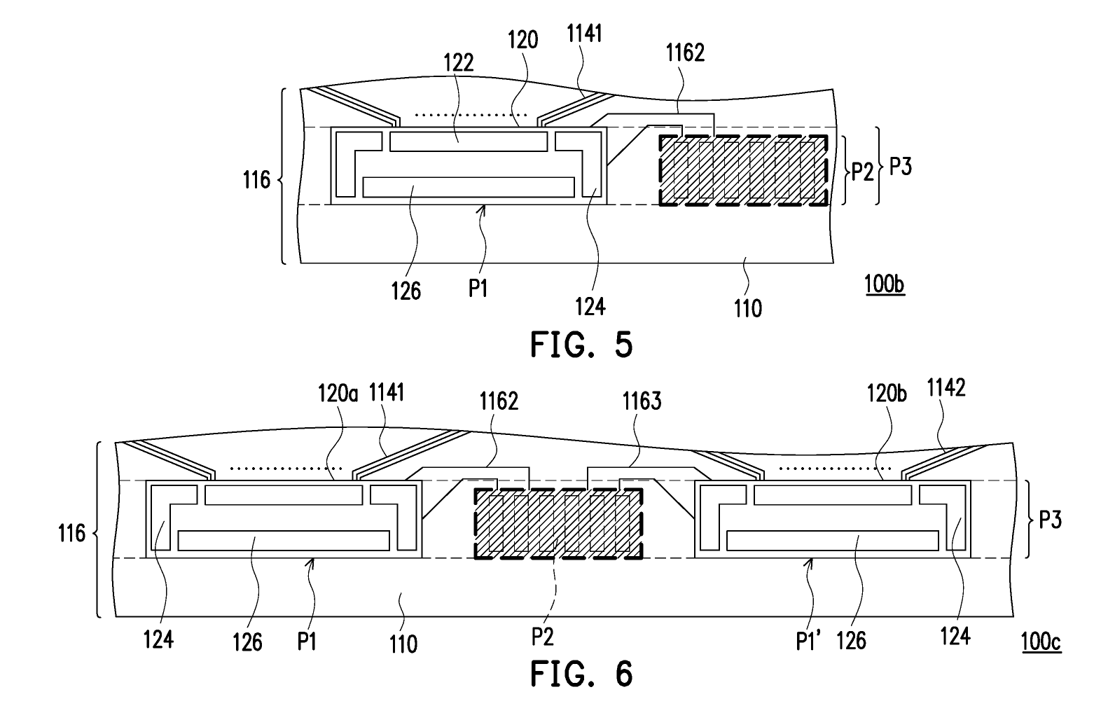

In some embodiments, the chip 120 may further include an active surface (e.g. a bottom surface) facing the substrate 110, with a plurality of bumps such as output bumps 122 and a plurality of input bumps 124 and/or 126 disposed on the active surface. It is noted that the reference numbers of 122, 124, 126 in FIG. 2, FIG. 3, FIG. 5, and FIG. 6 are illustrated as a region where the corresponding bumps (e.g. output bumps, input bumps, dummy bumps) are disposed. In the present embodiment, the output bumps 122 may be disposed on a side of the active surface closer to the active area 112 and be electrically connected to the fan-out lines 1141. The input bumps 124 and/or 126 may be disposed on the rest of the sides the active surface and electrically connected to the connecting lines 1162.

In some embodiments, the input bumps 124 are disposed on a side of the active surface closer to the connecting region P2 and the input bumps 124 are electrically connected to the connecting portion 1161 through the connecting lines 1162. In some embodiments, the chip 120 may further include a plurality of dummy bumps 126 disposed on the rest of the sides of the active surface, so that stress applied on the chip 120 can be distributed more evenly. However, the arrangement of the bumps illustrated in FIG. 2 is merely for illustration, and the disclosure does not limit the arrangement of the bumps on the chip 120.

In some embodiments, the substrate 110 may be a glass substrate and the chip 120 is mounted on the peripheral area 116 of the substrate 110. Namely, the display panel 100 may be a chip on glass (COG) package. In other embodiments, the substrate 110 may be a plastic flexible film, and the chip 120 is mounted on the peripheral area 116 thereof, which may be bended backward for further electrical connection. In other words, the display panel 100 may be a chip on plastic (COP) package. Certainly, the disclosure is not limited thereto.

In some embodiments, the peripheral area 116 further include an extensional region P3, which is extended from the chip region P1 along a longitudinal axis A1 of the chip 120, and the connecting region P2 is at least partially overlapped with the extensional region P3. The connecting lines 1162 are disposed on the peripheral area 116 and electrically connected between the chip 120 and the connecting portion 1161 as it is shown in FIG. 2. In some embodiments, the connecting lines 1162 are at least partially overlapped with the extensional region P3. On the contrary, the active area where the pixel array is disposed can be located along a short axis A2 of the chip 120. With the configuration where the connecting region P2 is overlapped with the extensional region P3, the required space for the peripheral area 116 can be reduced along the short axis A2 of the chip 120. Thereby, a narrower bezel (e.g. the peripheral area 116) of the display panel 100 can be achieved. In some embodiments, the width of a region where the connecting region P2 and the extensional region P3 are overlapped is the width of the bezel of the display panel 100 being reduced.

FIG. 3 illustrates a partial enlarged of a display panel according to an embodiment of the disclosure. It is noted that the display panel 100a shown in FIG. 3 contains many features same as or similar to the display panels 100 disclosed earlier with FIG. 1 and FIG. 2. For purpose of clarity and simplicity, detail description of same or similar features may be omitted, and the same or similar reference numbers denote the same or like components. The main differences between the display panel 100a shown in FIG. 3 and the display panels 100 disclosed earlier with FIG. 1 and FIG. 2 are described as follows.

In some embodiments, the display panel 100a may include more than one chips 120. For example, the display panel 100a may include a first chip 120a and a second chip 120b. Accordingly, the peripheral area 116 of the substrate 110 may include a first chip region P1 where the first chip 120a is mounted, a second chip region P1′ where the second chip 120b is mounted and a connecting region P2. In some embodiments, the first chip region P1 and the second chip region P1′ are arranged in a side by side manner. In other words, the first chip 120a and the second chip 120b mounted on the first chip region P1 and the second chip region P1′ respectively are disposed in the side by side manner. In some embodiments, the connecting portion P2 are disposed between the first chip region P1 and the second chip region P1′.

In some embodiments, the first chip 120a and the second chip 120b are electrically connected to the pixel array (e.g. the pixel array 1121 shown in FIG. 1). The connecting portion 1161, which is disposed on the connecting region P2 of the peripheral area 116, is configured to electrically connect a FPC board 130. In other words, the FPC board 130 is bonded to the connecting region P2 of the peripheral area 116 through the connecting portion 1161, and the FPC board 130 is configured to electrically connect the display panel 100a to a main board. In some embodiments, the connecting portion 1161 may include a plurality of bonding pads as shown in FIG. 3. In some embodiments, the connecting lines 1162, 1163 are electrically connected between the chips 120a, 120b and the connecting portion 1161. For example, the connecting lines 1162 are electrically connected between the first chip 120a and the connecting portion 1161, and the connecting lines 1163 are electrically connected between the second chip 120b and the connecting portion 1161.

In some embodiments, the first chip 120a and the second chip 120b may both be the display driver integrated circuits. Accordingly, the substrate 110 may further include a plurality of fan-out lines 1141, 1142 connected between the pixel array (e.g. the pixel array 1121 shown in FIG. 1) and the first chip 120a and the second chip 120b. For example, the fan-out lines 1141 are connected between the pixel array (e.g. the pixel array 1121 shown in FIG. 1) and the first chip 120a, and the fan-out lines 1142 are connected between the pixel array (e.g. the pixel array 1121 shown in FIG. 1) and the second chip 120b.

In the present embodiments, the peripheral area 116 further includes an extensional region P3, which is extended from the first chip region P1 to the second chip region P1′. In other words, the extensional region P3 is the region that is extended between the first chip region P1 and the second chip region P1′. In the present embodiment, the connecting region P2 for bonding the FPC board 130 is partially overlapped with the extensional region P3 extended between the first chip region P1 to the second chip region P1′. With the configuration of the connecting region P2 being partially overlapped with the extensional region P3, the required space for the peripheral area 116 can be reduced. Thereby, a narrower bezel (e.g. the peripheral area 116) of the display panel 100 can be achieved.

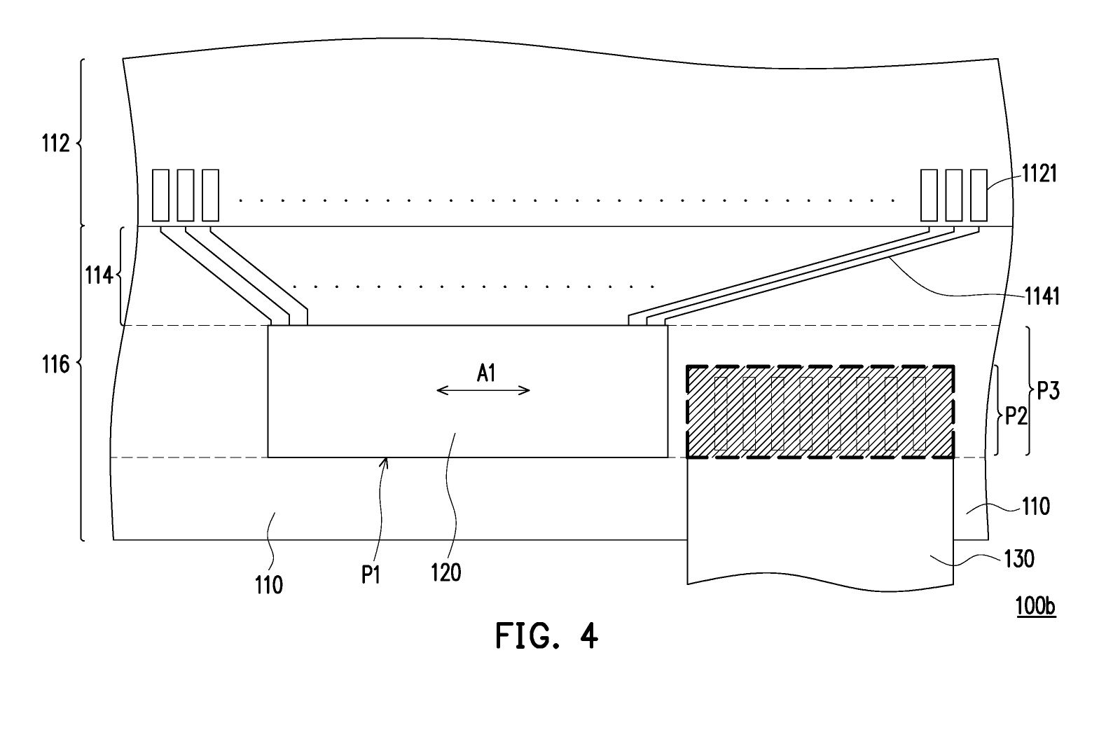

FIG. 4 illustrates a schematic view of a display panel according to an embodiment of the disclosure. FIG. 5 illustrates a partial enlarged of a display panel according to an embodiment of the disclosure. It is noted that the display panel 100b shown in FIG. 4 and FIG. 5 contains many features same as or similar to the display panels disclosed earlier with FIG. 1 and FIG. 2. For purpose of clarity and simplicity, detail description of same or similar features may be omitted, and the same or similar reference numbers denote the same or like components. The main differences between the display panel 100b shown in FIG. 4 and FIG. 5 and the display panels 100 disclosed earlier with FIG. 1 and FIG. 2 are described as follows.

Referring to FIG. 4 and FIG. 5, in some embodiments, the connecting portion P2 for bonding the FPC board 130 is completely located within the extensional region P3 extended from the chip region P1 along the longitudinal axis A1 of the chip 120. In other words, the connecting portion P2 for bonding the FPC board 130 is completely overlapped with the extensional region P3. Accordingly, a width of the connecting region P2 is substantially equal to or smaller than a width of the chip region P1 and a width of the extensional region P3. With the configuration of the connecting region P2 being completely overlapped with the extensional region P3, the required space for the peripheral area 116 can be further reduced. Thereby, a narrower bezel (e.g. the peripheral area 116) of the display panel 100 can be achieved. In such embodiment, the width of region of the connecting region P2 may be the width of the bezel of the display panel 100 being reduced.

FIG. 6 illustrates a partial enlarged of a display panel according to an embodiment of the disclosure. It is noted that the display panel 100c shown in FIG. 6 contains many features same as or similar to the display panel 100a disclosed earlier with FIG. 3. For purpose of clarity and simplicity, detail description of same or similar features may be omitted, and the same or similar reference numbers denote the same or like components. The main differences between the display panel 100c shown in FIG. 6 and the display panel 100a disclosed earlier with FIG. 3 are described as follows.

With now reference to FIG. 6, in some embodiments, the peripheral area 116 includes an extensional region P3, which is extended from the first chip region P1 to the second chip region P1′. In other words, the extensional region P3 is the region that is extended between the first chip region P1 and the second chip region P1′. In the present embodiment, the connecting region P2 for bonding the FPC board 130 is completely overlapped with the extensional region P3 extended between the first chip region P1 to the second chip region P1′. In other words, the connecting portion P2 is completely located within the extensional region P3. Accordingly, a width of the connecting region P2 is substantially equal to or smaller than a width of the first chip regions P1, and also be substantially equal to or smaller than a width of the second chip region P1′. In some embodiments, a width of the extensional region P3 may be the width of the first chip regions P1 or the width of the second chip region P1′, whichever is greater. Accordingly, the width of the connecting region P2 is substantially equal to or smaller than the width of the extensional region P3.

With the configuration of the connecting region P2 being completely overlapped with the extensional region P3, the required space for the peripheral area 116 can be further reduced along a short axis of the chip. Thereby, a narrower bezel (e.g. the peripheral area 116) of the display panel 100 can be achieved. In such embodiment, the width of region of the connecting region P2 may be the width of the bezel of the display panel 100 being reduced.

Based on the above discussions, it can be seen that the present disclosure offers various advantages. It is understood, however, that not all advantages are necessarily discussed herein, and other embodiments may offer different advantages, and that no particular advantage is required for all embodiments.

In sum, in a display panel of the disclosure, a peripheral area of a substrate includes a chip region where a chip is disposed, a connecting region for bonding a FPC board and an extensional region connecting region extended from the chip region along a longitudinal axis of the chip. The connecting region can be partially or completely overlapped with the extensional region. With such a configuration, the required space for the peripheral area can be further reduced along a short axis of the chip. Thereby, a narrower bezel (e.g. the peripheral area) of the display panel can be achieved. Thereby, the display panel of the disclosure has narrower bezel, which provides a larger viewable display area.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A display panel, comprising:
a substrate comprising an active area where a pixel array is located and a peripheral area at a side of the active area, and the peripheral area comprising a chip region and a connecting region;
a chip mounted on the chip region of the peripheral area and electrically connected to the pixel array;
a connecting portion disposed on the connecting region of the peripheral area and configured to be electrically connected to a flexible printed circuit (FPC) board, wherein the connecting region is at least partially overlapped with an extensional region extended from the chip region along a longitudinal axis of the chip; and
a plurality of connecting lines electrically connecting the chip and the connecting portion.

2. The display panel as claimed in claim 1, wherein the substrate further comprises a plurality of fan-out lines connected between the pixel array and the chip.

3. The display panel as claimed in claim 1, wherein the chip is a display driver integrated circuit.

4. The display panel as claimed in claim 1, wherein a width of the connecting region is substantially equal to or smaller than a width of the chip region.

5. The display panel as claimed in claim 1, wherein the connecting portion is completely located within the extensional region.

6. The display panel as claimed in claim 1, wherein the connecting portion is partially located within the extensional region and is partially located outside the extensional region.

7. A display panel, comprising:
a substrate comprising an active area where a pixel array is located and a peripheral area at a side of the active area, and the peripheral area comprising a first chip region, a second chip region and a connecting region, wherein the first chip region and the second chip region are arranged in a side by side manner;
a first chip and a second chip mounted on the first chip region and the second chip region respectively in the side by side manner, wherein the first chip and the second chip are electrically connected to the pixel array;
a connecting portion disposed on the connecting region of the peripheral area and configured to be electrically connected to a flexible printed circuit (FPC) board, wherein the connecting region is overlapped with an extensional region extended between the first chip region and the second chip region; and
a plurality of connecting lines electrically connected between the first chip and the connecting portion, and between the second chip and the connecting portion.

8. The display panel as claimed in claim 7, wherein the substrate further comprises a plurality of fan-out lines connected between the pixel array and the first chip and the second chip.

9. The display panel as claimed in claim 7, wherein the first chip and the second chip are display driver integrated circuit.

10. The display panel as claimed in claim 7, wherein a width of the connecting region is substantially equal to or smaller than both of a width of the first chip region and a width of the second chip region.

11. The display panel as claimed in claim 7, wherein the connecting portion is completely located within the extensional region.

12. The display panel as claimed in claim 7, wherein the connecting portion is partially located within the extensional region and is partially located outside the extensional region.

13. An electronic device, comprising:
a substrate, comprising a connecting portion;
at least one chip each mounted on the substrate; and
a plurality of connecting lines electrically connecting the chip and the connecting portion, wherein the connecting portion is configured to be electrically connected between a circuit board and the at least one chip, and the connecting region is at least partially overlapped with an extensional region extended from the chip region along a longitudinal axis of the chip.

14. The electronic device of claim 13, wherein the substrate further comprises an active area where a display panel is configured to be disposed.

15. The electronic device of claim 13, wherein the circuit board is a flexible printed circuit (FPC) board.
